(19) United States
(12) Patent Application Publication
(10) Pub. No.: US 2005/0199948 A1
(43) Pub. Date: Sep. 15, 2005

(54) Fin field effect transistors with epitaxial extension layers and methods of forming the same

(76) Inventors: Jong-Wook Lee, Gyeonggi-do (KR); Deok-Hyung Lee, Gyeonggi-do (KR)

Correspondence Address: MYERS BIGEL SIBLEY & SAJOVEC, PO BOX 37428, RALEIGH, NC, 27627, US

(21) Appl. No.: 11/074,516

(22) Filed: Mar. 8, 2005

(30) Foreign Application Priority Data
Mar. 9, 2004 (KR) 2004-15856

(51) Int. Cl. H01L 29/76

(52) U.S. Cl. 257/327

(57) ABSTRACT

A fin field-effect transistor (FinFET) device includes a fin-shaped semiconductor active region vertically protruding from a substrate and a gate structure on an upper surface and sidewalls of the fin-shaped semiconductor active region at a first portion thereof. The FinFET further includes a semiconductor epitaxial extension layer on the upper surface and sidewalls of the fin-shaped semiconductor active region at second portions thereof on opposite sides of the gate structure. The semiconductor epitaxial extension layer has a width that is greater than a width of the fin-shaped semiconductor active region at the first portion thereof. Related methods are also discussed.

### CROSS-REFERENCE TO RELATED APPLICATIONS

This application claims priority from Korean Patent Application No. 10-2004-0015856 filed on Mar. 9, 2004, the contents of which is hereby incorporated by reference herein in its entirety.

### BACKGROUND OF THE INVENTION

1. Field of the Invention

The present invention relates to semiconductor devices, and more particularly, to fin field-effect transistors (Fin FETs) and methods of forming the same.

2. Description of the Related Art

Recently semiconductor devices have been developed which can operate at both high speeds and low voltages. Device manufacturing processes have also been developed which may allow for higher degrees of device integration.

In FETs, it may be desirable to reduce the length of the channel region for high-speed operation. However, as channel length is reduced, the electric field produced by the drain voltage may have a greater effect on the channel region. As such, the ability of the gate electrode to control the channel of the FET may be deteriorated due to short channel effects.

In addition, when ion concentration in the channel region is increased to control the threshold voltage of the FET, carrier mobility in the channel region may be reduced, thereby decreasing drive current and increasing junction leakage current between the source and drain of the device.

FETs may be formed on a silicon-on-insulator (SOI) substrate and/or may include a fin-shaped active region to address some of the above problems. The SOI substrate may include an insulator layer and an upper silicon layer sequentially stacked on a bulk-silicon substrate. The Fin FET may include a three-dimensional channel region vertically protruding from the substrate.

A FET formed on a SOI substrate may be advantageous in that junction capacitance may be reduced and drive current may be increased. In addition, such devices may be more highly integrated and stably manufactured. However, FETs formed on a SOI substrate may also suffer from problems, such as variation in threshold voltage due to non-uniformity of the upper silicon layer, decrease in drive current due to additional heat caused by the insulation layer on the lower portion of the substrate, and floating channel effects.

To address some of the above problems with FETs formed on a SOI substrate, the thickness of the upper silicon layer may be increased. In addition, circuits may be designed specifically for SOI substrates. However, the increased thickness of the upper silicon layer may result in reduced device integration, and circuit designs developed specifically for SOI substrates may be difficult to implement due to potential technical problems and increased costs, such as the costs associated with employing a design engineer.

Fin FETs may include a vertically protruding fin-shaped semiconductor active region, which may also be referred to as a fin or an active fin, and a gate covering both sidewalls and a top surface of the fin. Accordingly, the gate may control current passing through a channel region formed at both sidewalls and the top surface of the fin. Thus, short channel effects may effectively be reduced. Alternatively, the channel region may be formed only at both sidewalls of the fin.

However, in Fin FETs, the width of the source/drain regions may be limited by the width of the fin structure. Thus, parasitic resistance may be considerably increased at the source/drain regions.

### SUMMARY OF THE INVENTION

According to some embodiments of the present invention, a fin field-effect transistor (FinFET) device may include a fin-shaped semiconductor active region vertically protruding from a substrate and a gate structure on an upper surface and sidewalls of the fin-shaped semiconductor active region at a first portion thereof. The device may further include a semiconductor epitaxial extension layer on the upper surface and sidewalls of the fin-shaped semiconductor active region at second portions thereof on opposite sides of the gate structure.

In some embodiments, the semiconductor epitaxial extension layer may have a width that is greater than a width of the fin-shaped semiconductor active region at the first portion thereof. For example, the fin-shaped semiconductor active region may have a width of about 40 nm or less, and the semiconductor epitaxial extension layer may have a width of about 50 nm or greater.

In other embodiments, the second portions of the fin-shaped semiconductor active region and the semiconductor epitaxial extension layer thereon may be source/drain regions. The device may further include source/drain contact regions adjacent the source/drain regions at end portions of the fin-shaped semiconductor active region and oriented perpendicular thereto. The source/drain contact regions may have a width that is greater than a width of the source/drain regions.

In some embodiments, the second portions of the fin-shaped semiconductor active region comprise “T”-shaped end portions.

In other embodiments, the device may include a lower spacer on lower sidewalls of the gate structure and an upper spacer on upper sidewalls of the gate structure. An upper surface of the lower spacer may have a height that is greater than or equal to a height of the fin-shaped semiconductor active region at the first portion thereof. Also, the lower spacer may be formed of a material having an etching rate different from an etching rate of the upper spacer. For example, the upper spacer may be formed of silicon nitride, and the lower spacer may be formed of silicon oxide.

In some embodiments, the substrate may be a silicon-on-insulator (SOI) substrate, and the fin-shaped semiconductor active region and the semiconductor epitaxial extension region may be formed of silicon.

In other embodiments, the gate structure may include a gate insulating pattern on the upper surface and sidewalls of the fin-shaped semiconductor active region at the first portion thereof and a gate conductive pattern on the gate insulating pattern. The gate structure may be oriented in a direction perpendicular to that of the fin-shaped semiconductor active region.

According to some embodiments of the present invention, a method of forming a FinFET device may include forming a fin-shaped semiconductor active region vertically protruding from a substrate, and forming a gate structure on an upper surface and sidewalls of the fin-shaped semiconductor active region at a first portion thereof. A semiconductor extension layer may be epitaxially grown on the upper surface and sidewalls of the fin-shaped semiconductor active region at second portions thereof on opposite sides of the gate structure to increase a width of the second portions of the fin-shaped semiconductor active region relative to the first portion thereof.

In some embodiments, the method may include forming source/drain regions in the second portions of the fin-shaped semiconductor active region and the semiconductor extension layer thereon.

In other embodiments, the method may include forming a lower spacer on lower sidewalls of the gate structure and forming an upper spacer on upper sidewalls of the gate structure. The upper spacer may be a silicon nitride upper spacer, and the lower spacer may be a silicon oxide lower spacer. The lower spacer may be formed such that an upper surface of the lower spacer may have a height that is greater than or equal to a height of the fin-shaped semiconductor active region at the first portion thereof.

In some embodiments, forming the upper spacer and the lower spacer may include forming a first insulation layer on the gate structure and the fin-shaped semiconductor active region. A portion of the first insulation layer may be removed to expose upper sidewalls of the gate structure. For example, a portion of the first insulation layer may be removed by planarizing the first insulation layer using chemical-mechanical polishing to expose a top portion of the gate structure, and then anisotropically etching the first insulation layer to expose upper sidewalls of the gate structure. A second insulation layer may be formed on the exposed upper sidewalls of the gate structure and may be selectively etched to form the upper spacer. The first insulation layer may be selectively etched using the upper spacer as an etching mask to form the lower spacer.

In other embodiments, forming the gate structure may include forming a gate insulating layer on the upper surface and sidewalls of the fin-shaped semiconductor active region. A gate conductive layer may be formed on the gate insulating layer on the upper surface and sidewalls of the fin-shaped semiconductor active region, and a hard mask layer may be formed on the gate conductive layer. The hard mask layer, the gate conductive layer, and the gate insulating layer may then be removed from the second portions of the fin-shaped semiconductor active region to form the gate structure on the first portion thereof in a direction perpendicular to that of the fin-shaped semiconductor active region.

In some embodiments, epitaxially growing a semiconductor extension layer may include epitaxially growing the semiconductor extension layer using a selective epitaxial growth process comprising at least one of low-pressure chemical vapor deposition (LPCVD), ultra high vacuum chemical vapor deposition (UHVCVD), atmospheric pressure chemical vapor deposition (APCVD), and/or molecular beam epitaxy (MBE).

In other embodiments, forming the fin-shaped semiconductor active region may include forming an upper silicon layer on a silicon-on-insulator (SOI) substrate including a bulk silicon layer and a buried oxide layer thereon. The upper silicon layer may be selectively etched to form the fin-shaped semiconductor active region on the SOI substrate. In some embodiments, the upper silicon layer may be selectively etched to form a fin-shaped semiconductor active region having “T”-shaped end portions.

In still other embodiments, forming the fin-shaped semiconductor active region may further include forming source/drain contact regions integrally extending from end portions of the fin-shaped semiconductor active region and oriented perpendicular thereto. The source/drain contact regions may have a width that is greater than a width of the fin-shaped semiconductor active region.

### BRIEF DESCRIPTION OF THE DRAWINGS

FIG. 1 is perspective view illustrating Fin FETs according to some embodiments of the present invention.

FIGS. 2A to 2G are perspective views illustrating exemplary operations for forming Fin FETs according to some embodiments of the present invention.

FIG. 3 is a perspective view illustrating the fin-shaped semiconductor active region of the Fin FET shown in FIG. 1.

FIG. 4 is perspective view illustrating Fin FETs according to further embodiments of the present invention.

FIG. 5 is a perspective view illustrating the fin-shaped semiconductor active region of the Fin FET shown in FIG. 4.

### DETAILED DESCRIPTION OF EMBODIMENTS OF THE INVENTION

The present invention now will be described more fully hereinafter with reference to the accompanying drawings, in which embodiments of the invention are shown. However, this invention should not be construed as limited to the embodiments set forth herein. Rather, these embodiments are provided so that this disclosure will be thorough and complete, and will fully convey the scope of the invention to those skilled in the art. In the drawings, the thickness of layers and regions are exaggerated for clarity. Like numbers refer to like elements throughout.

It will be understood that when an element such as a layer, region or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present.

It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

It will also be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present invention.

Furthermore, relative terms, such as “lower” or “bottom” and “upper” or “top,” may be used herein to describe one element's relationship to another elements as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower”, can therefore, encompasses both an orientation of “lower” and “upper,” depending of the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

The terminology used in the description of the invention herein is for the purpose of describing particular embodiments only and is not intended to be limiting of the invention. As used in the description of the invention and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items.

Embodiments of the invention are described herein with reference to cross-section illustrations that are schematic illustrations of idealized embodiments (and intermediate structures) of the invention. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the invention.

Unless otherwise defined, all terms used in disclosing embodiments of the invention, including technical and scientific terms, have the same meaning as commonly understood by one of ordinary skill in the art to which this invention belongs, and are not necessarily limited to the specific definitions known at the time of the present invention being described. Accordingly, these terms can include equivalent terms that are created after such time. All publications, patent applications, patents, and other references mentioned herein are incorporated by reference in their entirety.

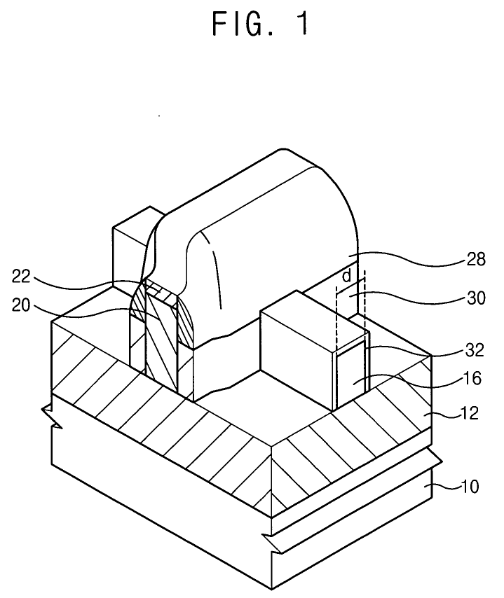

FIG. 1 is perspective view illustrating Fin FETs according to some embodiments of the present invention.

Referring now to FIG. 1, a fin-shaped semiconductor active region 16, also referred to herein as a fin and/or an active fin, is formed vertically protruding from a substrate 10 in a first direction. The substrate 10 may be a bulk-silicon substrate including a buried oxide layer 12, and the fin-shaped active region 16 may be formed of a semiconductor material such as silicon.

The fin 16 may have a width d of no more than about 40 nm, as a gate electrode may control current at both sidewalls of the fin 16 when the width of the fin 16 is sufficiently narrow. In addition, the fin 16 vertically protrudes from the buried oxide layer 12.

A gate structure is formed on the substrate 10 and on the fin 16 in a second direction that is different from the first direction. For example, the second direction may be perpendicular to the first direction, such that the gate structure is oriented to be perpendicular to the fin 16. The gate structure includes a gate insulation pattern (not shown), a gate conductive pattern 20, and a hard mask pattern 22, which are sequentially stacked on the substrate 10.

The gate conductive pattern 20 may be formed of doped polysilicon, metal, and/or metal silicide. The gate conductive pattern 20 may also be a multi-layer pattern including at least two layers, such as a doped polysilicon layer, a metal layer, and/or a metal silicide layer. In the embodiments illustrated in FIG. 1, the gate conductive pattern 20 is formed of doped polysilicon, and the hard mask pattern 22 is formed of silicon nitride.

Still referring to FIG. 1, a spacer is formed on sidewalls of the fin 16. The spacer and includes two different vertically-stacked layers, such that a lower spacer 30 is formed at a lower portion of the gate structure and an upper spacer 28 is formed at an upper portion of the gate structure. As such, the spacer may not be formed on sidewalls of the fin 16, except at portions of the fin 16 adjacent the gate structure.

The lower spacer 30 is formed of an insulation material that has an etch selectivity with respect to the hard mask pattern 22. For example, the lower spacer 30 may be formed of silicon oxide. The upper spacer 28 is formed of an insulation material that has an etch selectivity with respect to the lower spacer 30. For example, the upper spacer 28 may be formed of silicon nitride.

A top surface of the lower spacer 30 has a height that is greater than or equal to a height of a top surface of the fin 16. As shown in the embodiments of FIG. 1, the top surface of the lower spacer 30 is equal in height to the top surface of the fin 16. The upper and lower spacers 28 and 30 cover the sidewalls of the gate structure. Thus, the gate structure is covered by the spacer and the hard mask pattern 22.

A semiconductor epitaxial extension layer 32 is formed on an upper surface and sidewalls of the fin 16 in the first and second directions, adjacent both sidewalls of the lower spacer 30. The semiconductor epitaxial extension layer 32 may be formed of silicon grown by a selective epitaxial process.

As the semiconductor epitaxial extension 32 covers a top surface and both side walls of the fin 16, an upper surface of the semiconductor epitaxial extension layer 32 has a width that is greater than the width d of the fin 16. In the embodiments illustrated in FIG. 1, the upper surface of the semiconductor epitaxial extension layer 32 has a width of at least about 50 nm. In addition, the active extension layer 32 vertically protrudes from the substrate 10 to a greater extent than the fin 16.

Source/drain regions are formed in the semiconductor epitaxial extension layer 32 and the portion of the fin 16 under the semiconductor epitaxial extension layer 32. In other words, the semiconductor epitaxial extension layer 32 and the portion of the fin 16 under the semiconductor epitaxial extension layer 32 function as preliminary regions for forming the source/drain regions.

According to the Fin FET illustrated in the embodiments of FIG. 1, the gate structure is formed directly on the top surface and both sidewalls of the fin 16 at a first portion thereof where a channel region may be formed. Thus, the gate may control the current passing through the channel in a Fin FET more easily than in a conventional FET.

In addition, source/drain regions are formed at the semiconductor epitaxial extension layer, which has a width that is greater than the width d of the fin 16. In contrast, conventional Fin FETs may have smaller fin widths; thus, the source/drain regions in conventional Fin FETs may be small enough such that parasitic resistance may be increased. However, Fin FETs according to some embodiments of the present invention have increased fin widths due to the epitaxial extension layer; thus the source/drain region regions are also enlarged and parasitic resistance at the source/drain regions may be reduced. Accordingly, drive current may be increased in Fin FETs according to some embodiment of the present invention.

Further, according to some embodiments of the present invention, low-resistance source/drain regions may be formed in second portions of the fin-shaped active region and in the semiconductor epitaxial extension layer thereon at opposite sides of the gate structure. Due to the epitaxial growth process, the source/drain regions may be symmetrical to each other. Accordingly, electrical characteristics of the source/drain regions may not be altered even if the source and the drain are exchanged with each other. Accordingly, circuits including Fin FETs according to some embodiments of the present invention may be more stably operated.

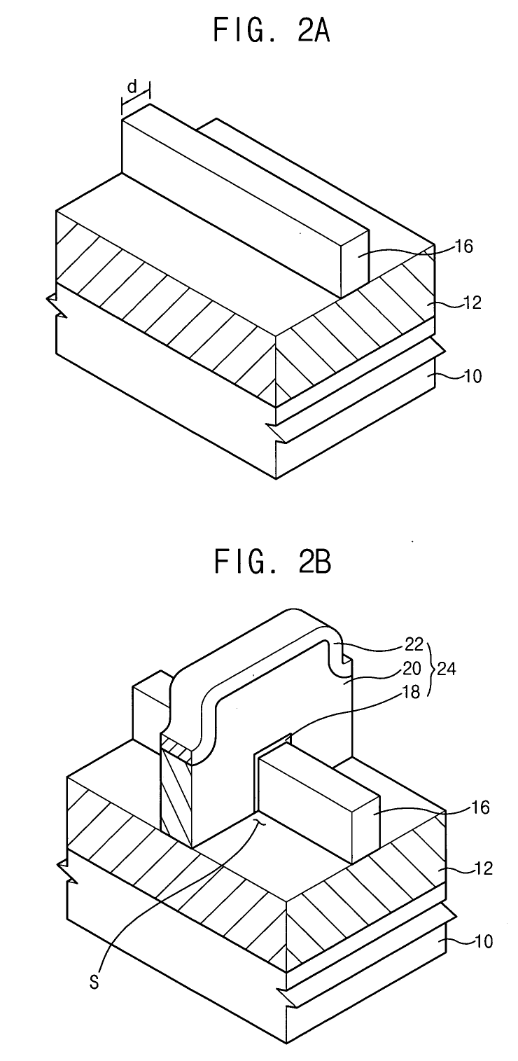

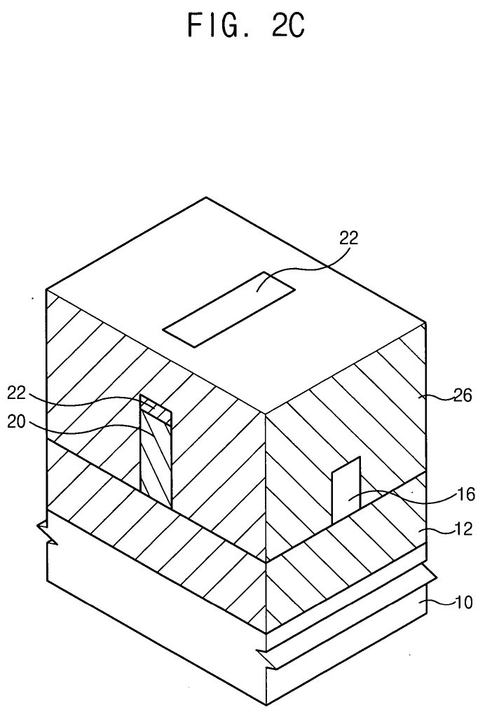

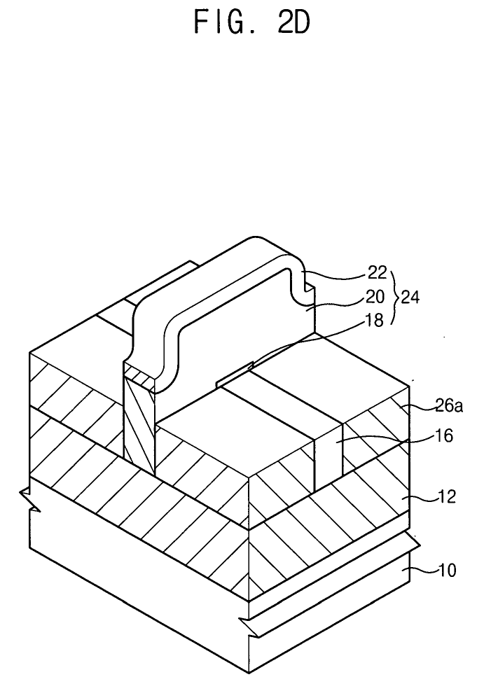

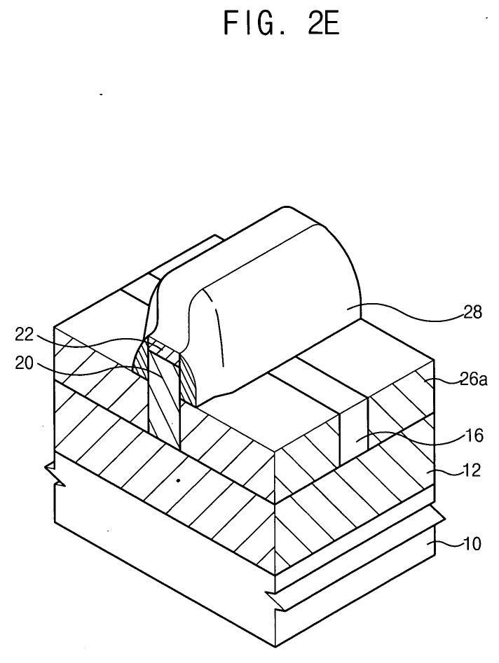

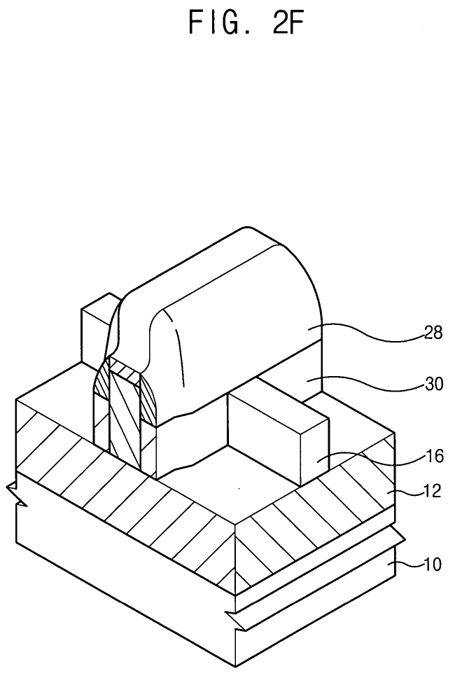

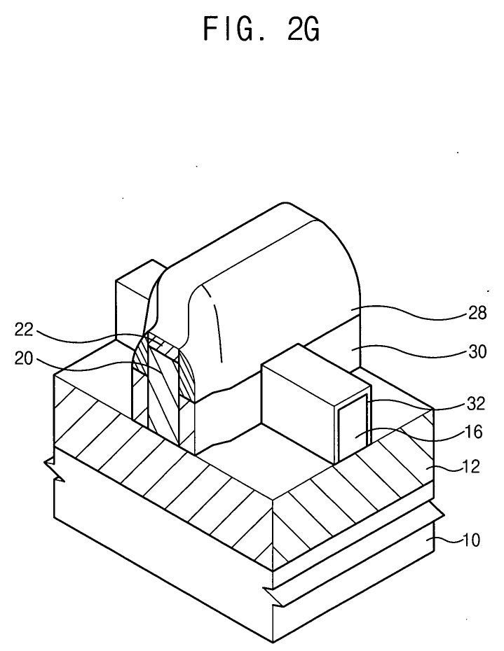

FIGS. 2A to 2G are perspective views illustrating exemplary operations for forming Fin FETs according to some embodiments of the present invention.

Referring now to FIG. 2A, a bulk-silicon substrate 10 is provided, and a buried oxide layer 12 and an upper silicon layer are sequentially formed on the bulk-silicon substrate to thereby form a silicon-on-insulation (SOI) substrate.

A photoresist film is formed on the upper silicon layer and is selectively exposed to light and developed to form a photoresist pattern (not shown) on the upper silicon layer. Then, the upper silicon layer is etched using the photoresist pattern as an etching mask until a surface of the buried oxide layer 12 is exposed, thereby forming a fin-shaped semiconductor active region 16 in a first direction on the buried oxide layer 12. In other words, the fin-shaped semiconductor active region 16 vertically protrudes from the buried oxide layer 12 of the SOI substrate. A Fin FET according to embodiments of the present invention may be formed on the fin 16 in subsequent processes. The fin 16 has a width d of no more than about 40 nm, so that a gate electrode may be formed at a first portion thereof to control the channel region at both sidewalls of the fin 16.

Alternatively, a hard mask (not shown) is formed on the upper silicon layer, and the upper silicon layer is selectively etched using the hard mask as an etching mask to form the fin 16. The hard mask may then be removed from the upper silicon layer, or may remain on the upper silicon layer after forming the fin 16. When the hard mask remains on the upper silicon layer, the Fin FET may have a double-gate structure. Alternatively, when the hard mask is removed, the Fin FET may have a triple-gate structure.

Referring now to FIG. 2B, a gate structure 24 is formed on the buried oxide layer 12 and on the fin 16 in a second direction that is different from the first direction. For example, the second direction may be perpendicular to the first direction, such that the gate structure 24 is oriented perpendicular to the fin 16. The gate structure 24 is formed as follows.

First, a gate insulation layer is formed on surfaces of the fin 16. For example, the gate insulation layer may be a thermal oxide layer formed by thermally oxidizing the fin 16, or may be a silicon oxide layer formed by depositing silicon oxide on surfaces of the fin 16. In the embodiments illustrated in FIG. 2B, the gate insulation layer is formed of a thermal oxide layer, which may improve operational characteristics of the Fin FET. The gate insulation layer is selectively formed on an upper surface and on both sidewalls of the fin 16.

A gate conductive layer is then formed on the gate insulation layer and the buried oxide layer 12. The gate conductive layer may be formed of doped polysilicon, metal, and/or metal silicide. The gate conductive layer may also be a multi-layer pattern including at least two layers, such as a doped polysilicon layer, a metal layer and/or a metal silicide layer. In the embodiments illustrated in FIG. 2B, a doped polysilicon layer is used for the gate conductive layer, as a doped polysilicon layer may have favorable step coverage, thermal stability, and etching characteristics.

A hard mask layer is then formed on the gate conductive layer. The hard mask layer may function not only as an etching mask for patterning underlying layers, but also as a polishing stop layer during a subsequent polishing process. The hard mask layer may be formed of silicon nitride.

The hard mask layer is partially removed by a conventional photolithography process, thereby forming a hard mask pattern 22 on a portion of the gate conductive layer. The gate conductive layer and the gate insulation layer are etched using the hard mask pattern 22 as an etching mask, forming a gate insulation pattern 18 and a gate conductive pattern 20 on the buried oxide layer 12 and the fin 16. As such, the gate structure 24 includes the gate insulation pattern 18, the gate conductive pattern 20, and the hard mask pattern 22.

Referring now to FIG. 2C, a silicon oxide layer 26 is formed on the buried oxide layer 12 and the fin 16 to a thickness sufficient to fill a space S (not shown) between two adjacent gate structures. As such, the gate structure 24 is covered by the silicon oxide layer 26. The silicon oxide layer 26 is formed of a material having a different etching rate than the hard mask pattern 22 under similar etching conditions.

The silicon oxide layer 26 is then planarized, for example, by a chemical mechanical polishing (CMP) process until a top surface of the hard mask pattern 22 is exposed. As such, the hard mask pattern 22 may function as a polishing stop layer in the CMP process. Accordingly, the silicon oxide layer 26 can be precisely recessed to a desired thickness using the CMP process, and as such, subsequent processes may be more easily optimized.

Although the silicon oxide layer 26 is planarized until the top surface of the hard mask pattern 22 is exposed in the embodiments described above, it may not be necessary to expose the hard mask pattern 22 in some embodiments. Thus, the duration of the CMP may be varied in accordance with desired processing conditions.

Referring now to FIG. 2D, the silicon oxide layer 26 is anisotropically etched to a predetermined depth. As the etching rate of the silicon oxide layer 26 is higher than that of the hard mask pattern 22, a silicon oxide pattern 26a is formed. Accordingly, an upper portion of the gate structure 24 is exposed, while a lower portion of the gate structure 24 remains covered by the silicon oxide pattern 26a. The silicon oxide pattern 26a is used to form a lower spacer on the gate structure 24 in a subsequent process. A top surface of the silicon oxide pattern 26a is formed to a height that is greater than or equal to the height of a top surface of the fin 16. In the embodiments illustrated in FIG. 2D, the top surface of the silicon oxide pattern 26a is equal in height to the top surface of the fin 16. When the top surface of the silicon oxide pattern 26a is lower than the top surface of the fin 16, an upper spacer may be formed at both sidewalls of the fin 16 in a subsequent process, which may be disadvantageous.

Referring to FIG. 2E, a silicon nitride layer having a different etching rate than the silicon oxide layer 26a is formed on the gate structure 24 and the silicon oxide pattern 26a. Then, the silicon nitride layer is anisotropically etched. As the etching rate of the silicon nitride layer is higher than that of the silicon oxide layer 26a, an upper spacer 28 is formed on upper sidewalls of the gate structure 24.

Referring now to FIG. 2F, the silicon oxide pattern 26a is anisotropically etched using the upper spacer 28 as an etching mask, thereby forming a lower spacer 30. Note that a general spacer may be formed by performing an anisotropic etching process without using an etching mask. However, the lower spacer 30 of the embodiments illustrated in FIG. 2F is formed by anisotropically etching the silicon oxide pattern 26a using the upper spacer 28 as an etching mask. Accordingly, the silicon oxide pattern 26a is removed from the buried oxide layer 12 except for portions thereof under the upper spacer 28. Thus, the upper surface and both sidewalls of the fin 16 are exposed, and the silicon oxide pattern 26a remaining under the upper spacer 28 forms the lower spacer 30. As such, a spacer is not formed at sidewalls of the fin 16, except at portions adjacent both sidewalls of the gate structure 24.

The anisotropic etching process may be performed such that the silicon oxide pattern 26a is removed to expose the buried oxide layer 12 without etching the buried oxide layer 12. When a portion of the buried oxide layer 12 is removed by the etching process, the remaining buried oxide layer 12 may extend lower side walls of the fin 16, which may thereby make subsequent processes more difficult. In contrast, when the silicon oxide pattern 26a is not completely removed and a portion thereof remains on the buried oxide layer 12, a lower portion of the fin 16 may be buried in the silicon oxide pattern 26a. As such, the effective height of the fin 16 may be decreased.

In the embodiments illustrated in FIG. 2F, the upper spacer 28 and the hard mask pattern 22 are formed of the same material, and the silicon oxide pattern 26a is formed of a material having a greater etching rate than the upper spacer 28 and the hard mask pattern 22. Therefore, very little of the hard mask pattern 22 is removed during the above etching process.

Referring now to FIG. 2G, a semiconductor epitaxial extension layer 32 is formed on an upper surface and sidewalls of the fin 16 adjacent both sides of the lower spacer 30. In other words, the semiconductor epitaxial extension layer 32 is formed on the fin 16 in the first and second directions on opposite sides of the gate structure 24, where source/drain regions may be formed in a subsequent process. The semiconductor epitaxial extension layer 32 may be formed by a selective epitaxial growth process, such as pressure chemical vapor deposition (LPCVD) process, an ultra high vacuum chemical vapor deposition (UHVCVD) process, an atmospheric pressure chemical vapor deposition (APCVD) process, and/or a molecular beam epitaxy (MBE) process. In some embodiments, the semiconductor epitaxial extension layer 32 may have an upper width of at least about 50 nm, which may reduce electrical resistance at the source/drain regions.

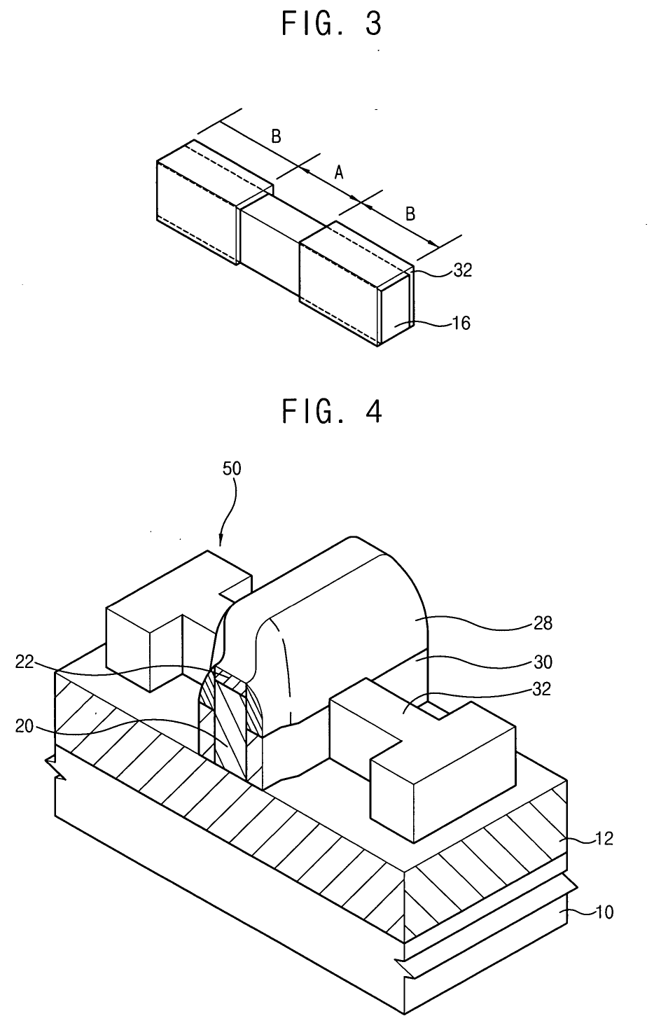

FIG. 3 is a perspective view illustrating the fin-shaped active region of the Fin FET of FIG. 1.

Referring now to FIGS. 2A-2G and FIG. 3, the semiconductor epitaxial extension layer 32 is formed along the upper surface and sidewalls of the fin 16 at opposite sides of the gate structure 24 which correspond to the source/drain regions. More particularly, the semiconductor epitaxial extension layer 32 is formed on the portions of the fin 16 designated as ‘B’ in FIG. 3. The semiconductor epitaxial extension layer 32 is not formed under the gate structure 24, which is formed on a portion of the fin 16 designated as ‘A’ in FIG. 3. In other words, the semiconductor epitaxial extension layer 32 is grown on the exposed surface of the fin 16 which is not covered by the gate structure 24. Thus the upper surface of the semiconductor epitaxial extension layer 32 is higher than the upper surface of the fin 16, and has a width that is greater than the width d of the fin 16.

Then, source/drain regions are formed at surface portions of the semiconductor epitaxial extension layer 32, including portions of the fin 16 under the epitaxial extension layer 32, by an ion implantation process.

According to some embodiments of the present invention, the source/drain regions are formed in the fin 16 and in the semiconductor epitaxial extension layer 32 which is formed on the fin 16 by an epitaxial growth process. Thus, the width of the source/drain regions may be increased when compared with source/drain regions of conventional Fin FETs. As the width of the source/drain regions increase, electrical resistance at the source/drain regions may decrease. As such, drive current for the Fin FET may be increased.

In addition, as the width may be increased at the same rate at both the source and drain regions of the Fin FET due to the epitaxial growth process, the source and drain structures may be symmetrical to each other. Thus, electrical characteristics of the source/drain regions may not be altered even if the source and the drain are exchanged with each other. Accordingly, circuits which include Fin FETs according to some embodiments of the present invention may be more stably operated.

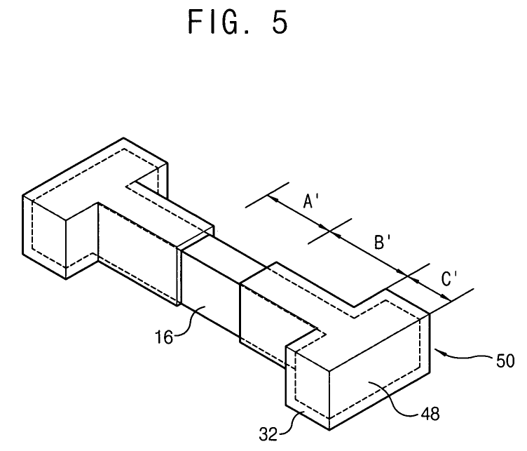

FIG. 4 is perspective view illustrating Fin FETs according to further embodiments of the present invention. FIG. 5 is a perspective view illustrating a fin-shaped active region of the Fin FET shown in FIG. 4, in which a semiconductor epitaxial extension layer is formed on the fin. Fin FETs according to further embodiments of the present invention may be similar in structure to other embodiments of the present invention, except for source/drain contact regions 50 which integrally extend from end portions of the fin (not shown) at opposite sides of the gate structure 24.

Referring to FIGS. 4 and 5, the source/drain contact regions 50 have a width that is greater than a width of the source/drain regions (illustrated as ‘B’ in FIG. 5). Thus, contact area at the source/drain regions may be increased.

Fin FETs according to further embodiments of the present invention may be formed in a similar manner as described with reference to FIGS. 2A to 2G, except that preliminary source/drain contact regions 48 may be formed simultaneously with the fin 16, such that the preliminary source/drain contact regions 48 extend from end portions of the fin 16. Further description is focused on exemplary operations for forming the source/drain contact regions 50. As such, description of operations which may be identical and/or similar to the exemplary operations illustrated in FIGS. 2A-2G may be omitted and/or briefly provided to avoid redundancy. In FIGS. 4 and 5, the same reference designators will be used to refer to the same or like parts as those shown in FIGS. 1 to 3.

Referring now to FIGS. 4 and 5, the buried oxide layer 12 and the upper silicon layer are sequentially stacked on the bulk-silicon substrate 10, and the upper silicon layer is partially removed, for example, by an etching process, thereby forming a fin-shaped action region 16 and preliminary source/drain contact regions 48. The preliminary source/drain contact regions 48 may have a width that is greater than that of the fin 16.

Similar processing steps as described with reference to FIGS. 2B to 2G are then performed to form Fin FETs according to further embodiments of the present invention.

More particularly, a gate structure is formed on the substrate in a direction that is different from that of the fin 16. A silicon oxide layer is formed on the buried oxide layer 12 and the fin 16 to a thickness sufficient to fill a space S between two adjacent gate structures, and is planarized by a conventional CMP process.

Then, the planarized silicon oxide layer is anisotropically etched, thereby forming a silicon oxide pattern adjacent sidewalls of the gate structure. Accordingly, an upper portion of the gate structure 24 is exposed while a lower portion of the gate structure 24 remains covered by the silicon oxide pattern. An upper surface of the silicon oxide pattern is formed to a height that is greater than or equal to a height of the upper surfaces of the active fin 16 and/or the preliminary source/drain contact regions 48.

A silicon nitride layer is then formed on the gate structure and on the silicon oxide pattern. The silicon nitride layer has an etching rate that is greater than that of the silicon oxide pattern under similar etching conditions. The silicon nitride layer is anisotropically etched, to form an upper spacer 28. The silicon oxide pattern is then etched using the upper spacer 28 as an etching mask to form a lower spacer 30 under the upper spacer 28.

A semiconductor epitaxial extension layer 32 is formed on exposed surfaces the fin 16 and the preliminary source/drain contact regions 48 at both sides of the lower spacer 30 by a conventional epitaxial growth process. In other words, the semiconductor epitaxial layer 32 is epitaxially grown on the upper surfaces and sidewalls of the fin 16 and the preliminary source/drain contact regions 48 on opposite sides of the gate structure.

As shown in FIG. 5, the semiconductor epitaxial extension layer 32 is formed along the upper surface and sidewalls of the fin 16 at both sides of the gate structure, which correspond to the source/drain regions (designated as ‘B’) and the preliminary source/drain contact regions (designated as ‘C’). The semiconductor epitaxial extension layer 32 is not formed under the gate structure 24 (designated as ‘A’). That is, the semiconductor epitaxial extension layer 32 is epitaxially grown on the upper surfaces and sidewalls of the fin 16 and the preliminary source/drain contact regions 48 at portions that are not covered by the gate structure. Accordingly, source/drain contact regions 50 are formed on the preliminary source/drain contact regions 48. Thus, the source/drain contact regions 50 have a width greater than that of the preliminary source/drain contact regions 48. In addition, the epitaxial extension layer 32 covers the top surface and both sidewalls of the preliminary source/drain contact regions 48. Thus, a top surface of the source/drain contact regions 50 is higher than the top surface of the portion of the fin 16 on which the gate of the Fin FET is formed.

According to some embodiments of the present invention, the source/drain regions are formed in fin 16 and in the semiconductor epitaxial extension layer 32 which is formed on the fin 16 by an epitaxial growth process. Thus, the width of the source/drain regions may be increased when compared with source/drain regions of conventional Fin FETs. As the width of the source/drain regions increase, electrical resistance at the source/drain regions may decrease and as such, drive current for the Fin FET may be increased.

In addition, as the width may be increased at the same rate at both the source and drain regions of the Fin FET due to the epitaxial growth process, the source and drain structures may be symmetrical to each other. Thus, electrical characteristics of the source/drain regions may not be altered even if the source and the drain are exchanged with each other. Accordingly, circuits including Fin FETs according to some embodiments of the present invention may be more stably operated.

While the present invention has been particularly shown and described with reference to exemplary embodiments thereof, it will be understood by those skilled in the art that various changes in form and details may be made therein without departing from the spirit and scope of the invention as defined by the appended claims and their equivalents.

1. A FinFET device, comprising:
a fin-shaped semiconductor active region vertically protruding from a substrate;
a gate structure on an upper surface and sidewalls of the fin-shaped semiconductor active region at a first portion thereof; and
a semiconductor epitaxial extension layer on the upper surface and sidewalls of the fin-shaped semiconductor active region at second portions thereof on opposite sides of the gate structure.

2. The device of claim 1, wherein the semiconductor epitaxial extension layer has a width that is greater than a width of the fin-shaped semiconductor active region at the first portion thereof.

3. The device of claim 1, wherein the fin-shaped semiconductor active region has a width of about 40 nm or less, and wherein the semiconductor epitaxial extension layer has a width of about 50 nm or greater.

4. The device of claim 1, wherein the second portions of the fin-shaped semiconductor active region and the semiconductor epitaxial extension layer thereon comprise source/drain regions.

5. The device of claim 4, further comprising:
source/drain contact regions adjacent the source/drain regions at end portions of the fin-shaped semiconductor active region and oriented perpendicular thereto,
wherein the source/drain contact regions have a width that is greater than a width of the source/drain regions.

6. The device of claim 1, wherein the second portions of the fin-shaped semiconductor active region comprise “T”-shaped end portions.

7. The device of claim 1, further comprising:
a lower spacer on lower sidewalls of the gate structure; and
an upper spacer on upper sidewalls of the gate structure.

8. The device of claim 7, wherein an upper surface of the lower spacer has a height that is greater than or equal to a height of the fin-shaped semiconductor active region at the first portion thereof.

9. The device of claim 7, wherein the lower spacer comprises a material having an etching rate different from an etching rate of the upper spacer.

10. The device of claim 7, wherein the upper spacer comprises silicon nitride, and wherein the lower spacer comprises silicon oxide.

11. The device of claim 1, wherein the substrate comprises a silicon-on-insulator (SOI) substrate, and wherein the fin-shaped semiconductor active region and the semiconductor epitaxial extension region comprise silicon.

12. The device of claim 1, wherein the gate structure comprises a gate insulating pattern on the upper surface and sidewalls of the fin-shaped semiconductor active region at the first portion thereof and a gate conductive pattern on the gate insulating pattern, and wherein the gate structure is oriented in a direction perpendicular to that of the fin-shaped semiconductor active region.

13. A method of forming a FinFET device, comprising:
forming a fin-shaped semiconductor active region vertically protruding from a substrate;
forming a gate structure on an upper surface and sidewalls of the fin-shaped semiconductor active region at a first portion thereof; and
epitaxially growing a semiconductor extension layer on the upper surface and sidewalls of the fin-shaped semiconductor active region at second portions thereof on opposite sides of the gate structure to increase a width of the second portions of the fin-shaped semiconductor active region relative to the first portion thereof.

14. The method of claim 13, further comprising:
forming source/drain regions in the second portions of the fin-shaped semiconductor active region and the semiconductor extension layer thereon.

15. The method of claim 13, further comprising:
forming a lower spacer on lower sidewalls of the gate structure; and
forming an upper spacer on upper sidewalls of the gate structure.

16. The method of claim 15, wherein forming the lower spacer comprises:
forming an upper surface of the lower spacer to a height that is greater than or equal to a height of the fin-shaped semiconductor active region at the first portion thereof.

17. The method of claim 15, wherein forming the upper spacer and the lower spacer comprises:
forming a first insulation layer on the gate structure and the fin-shaped semiconductor active region;
removing a portion of the first insulation layer to expose upper sidewalls of the gate structure;
forming a second insulation layer on the exposed upper sidewalls of the gate structure;
selectively etching the second insulation layer to form the upper spacer; and
selectively etching the first insulation layer using the upper spacer as an etching mask to form the lower spacer.

18. The method of claim 17, wherein removing a portion of the first insulation layer comprises:
planarizing the first insulation layer using chemical-mechanical polishing to expose a top portion of the gate structure; and then
anisotropically etching the first insulation layer to expose upper sidewalls of the gate structure.

19. The method of claim 15, wherein forming the upper spacer comprises forming a silicon nitride upper spacer, and wherein forming the lower spacer comprises forming a silicon oxide lower spacer.

20. The method of claim 13, wherein forming the gate structure comprises:
forming a gate insulating layer on the upper surface and sidewalls of the fin-shaped semiconductor active region;
forming a gate conductive layer on the gate insulating layer on the upper surface and sidewalls of the fin-shaped semiconductor active region;
forming a hard mask layer on the gate conductive layer; and
removing the hard mask layer, the gate conductive layer, and the gate insulating layer from the second portions of the fin-shaped semiconductor active region to form the gate structure on the first portion thereof in a direction perpendicular to that of the fin-shaped semiconductor active region.

21. The method of claim 13, wherein epitaxially growing a semiconductor extension layer comprises:
epitaxially growing the semiconductor extension layer using a selective epitaxial growth process comprising at least one of low-pressure chemical vapor deposition (LPCVD), ultra high vacuum chemical vapor deposition (UHVCVD), atmospheric pressure chemical vapor deposition (APCVD), and/or molecular beam epitaxy (MBE).

22. The method of claim 13, wherein forming the fin-shaped semiconductor active region comprises:
forming an upper silicon layer on a silicon-on-insulator (SOI) substrate including a bulk silicon layer and a buried oxide layer thereon; and
selectively etching the upper silicon layer to form the fin-shaped semiconductor active region on the SOI substrate.

23. The method of claim 22, wherein selectively etching the upper silicon layer comprises:
selectively etching the upper silicon layer to form a fin-shaped semiconductor active region having “T”-shaped end portions.

24. The method of claim 13, wherein forming the fin-shaped semiconductor active region further comprises:
forming source/drain contact regions integrally extending from end portions of the fin-shaped semiconductor active region and oriented perpendicular thereto,
wherein the source/drain contact regions have a width that is greater than a width of the fin-shaped semiconductor active region.
